(19) United States
(12) Patent Application Publication
(10) Pub. No.: US 2012/0006263 A1
(43) Pub. Date: Jan. 12, 2012

(54) FILM DEPOSITION APPARATUS

(75) Inventors: Shin Hashimoto, Itami-shi (JP); Tatsuya Tanabe, Itami-shi (JP)

(73) Assignee: SUMITOMO ELECTRIC INDUSTRIES, LTD., Osaka-shi (JP)

(21) Appl. No.: 12/999,973

(22) PCT Filed: Aug. 6, 2009
(86) PCT No.: PCT/JP09/63939

§ 371 Date: Dec. 17, 2010

(51) Int. Cl. B05C 9/14; H01L 21/00; C23C 16/34; B05C 11/00; C23C 16/46

(52) U.S. Cl. 118/712; 118/58; 118/725; 118/50

(57) ABSTRACT

When a film is to be deposited on a semiconductor substrate or the like in a heating ambient, the semiconductor substrate is caused to warp (curve) to a considerable extent merely due to an increased temperature. The warpage leads to problems such as degradation of the homogeneity of the quality of the film deposited on the substrate and a high possibility of generation of a crack in the substrate. Accordingly, a film deposition apparatus of the present invention heats the substrate both from above and from below a main surface of the substrate so that a temperature gradient (temperature difference) between the upper side and the lower side of the main surface is reduced and the warpage of the substrate is suppressed. More preferably a measurement unit for measuring the curvature or warpage of the substrate is included.

### TECHNICAL FIELD

The present invention relates to a film deposition apparatus depositing a thin film by vapor phase growth or vacuum vapor deposition on a main surface of a substrate, and more particularly to a film deposition apparatus controlling curve of a main surface of a semiconductor wafer due to heat, while depositing a thin film on the main surface of the semiconductor substrate.

### BACKGROUND ART

When a thin film is to be grown so as to form a semiconductor device on one main surface of a substrate which is for example a semiconductor substrate, a generally performed method exposes the top of one main surface of the semiconductor substrate to a gas of a constituent material for the thin film to be formed, while heating the substrate. As the material gas, for example, an organometallic compound of a group III nitride semiconductor to serve as cation, or a material gas containing a group V element to serve as anion is used. These material gases are fed onto the main surface of the heated semiconductor substrate to thereby grow the thin film on one main surface of the semiconductor substrate.

Here, conventional methods for heating the semiconductor substrate include, as illustrated in “Group III Nitride Semiconductor (Non-Patent Document 1), RF heating, resistance heating, and infrared lamp heating, for example. A technique of growing a thin film on a heated semiconductor substrate using a material gas (vapor phase) as described above is referred to as vapor phase growth. An apparatus for performing the vapor phase growth is provided with a susceptor as a member for setting a semiconductor substrate and heating the semiconductor substrate. The methods for heating a semiconductor substrate disclosed in Non-Patent Document 1 all set, on a susceptor, a semiconductor substrate to be heated.

FIG. 6 is a schematic diagram generally showing the inside of a conventionally-used film deposition apparatus depositing a film by the vapor phase growth. As shown in FIG. 6, conventionally-used film deposition apparatus 100 depositing a film by the vapor phase growth includes a heater 2 serving as a heating member and located below a main surface of a susceptor 1 for setting a substrate which is for example a semiconductor substrate 10 (in FIG. 6, the heater faces a main surface opposite to the side on which semiconductor substrate 10 is set). Namely, susceptor 1 and semiconductor substrate 10 are heated from below susceptor 1. A flow channel 3 for flowing a material gas therein is placed above susceptor 1 (in FIG. 6, the flow channel faces the side on which semiconductor substrate 10 is set). While heater 2 heats susceptor 1 and semiconductor substrate 10 thereon, a material gas which is a constituent of a thin film to be deposited is fed into flow channel 3 from a material gas nozzle 4 placed on one end (upstream) of flow channel 3, so that one main surface (upper main surface shown in FIG. 6) of semiconductor substrate 10 can be exposed to the material gas. Accordingly, on the main surface of heated semiconductor substrate 10, a thin film made of the fed material gas is deposited. At this time, a laser beam applied from a module 5 mounted on the ceiling (upper side) in film deposition apparatus 100 can be used to measure the curvature of semiconductor substrate 10 as described later, namely the extent of a curve with respect to the direction along the main surface of semiconductor substrate 10.

“Systems Products” (Non-Patent Document 2) uses data to illustrate that a considerable warpage (curve) occurs to a wafer which is a semiconductor substrate only due to an increased temperature. The warpage of the semiconductor substrate is caused by a difference between respective temperatures of the upper and lower sides of the semiconductor substrate due to a flow of heat generated by the increased temperature of the semiconductor substrate.

### PRIOR ART DOCUMENTS

### Non-Patent Documents

Non-Patent Document 1: “Group III Nitride Semiconductor”, Isamu Akazaki, Baifukan Co., Ltd., 1994, pp. 147-165
Non-Patent Document 2: “Systems Products” (online), Marubun Corporation (search made on Mar. 17, 2008) on the Internet <http://www.marubun.jp/product/thinfilm/other/qgc18e0000000db3.html>

### SUMMARY OF THE INVENTION

### Problems to be Solved by the Invention

In the above-described film deposition apparatus for growing a thin film, the susceptor which is a member for setting a semiconductor substrate and heating the semiconductor substrate is provided, under the present circumstances, in such a manner that the semiconductor substrate on which a thin film is to be grown is set on the upper side of the susceptor and the heater for heating the susceptor is provided on the lower side of the susceptor. The susceptor is then heated from below by the heater to thereby heat the semiconductor substrate mounted on the upper side of the susceptor. The method as used flows a gas of a constituent material for the thin film to be formed, on the upper side of the semiconductor substrate. In the case of the face down approach, the upper side and the lower side are replaced with each other. Specifically, on the lower side of the susceptor, the semiconductor substrate on which a thin film is to be grown is set and, on the upper side of the susceptor, the heater for heating the susceptor is placed. The susceptor is heated from above by the heater to thereby heat the semiconductor substrate placed on the lower side of the susceptor. The method as used flows a gas of a constituent material for the thin film to be formed, on the lower side of the semiconductor substrate.

In the case above, for example, in the case where the heater is placed on the lower side of the susceptor, the heat of the heater is transmitted from the lower side to the upper side of the susceptor and transmitted from the lower side to the upper side of the semiconductor substrate which is set on the upper side of the susceptor. Further, radiation to above the semiconductor substrate and heat transfer to the material gas cause heat to flow. Consequently, the upper side and the lower side with respect to the direction of the main surface of the semiconductor substrate have respective temperatures different from each other. Accordingly, the wafer which is a semiconductor substrate warps (curves) relative to the direction along the main surface. In the case where the heater is placed on the lower side of the susceptor, the lower side of the wafer has a higher temperature than the upper side thereof, and accordingly a warp is generated in the form that the lower side of the wafer is convex (downward convex). In the case of the face down approach for example where the heater is placed on the upper side of the susceptor, the upper side of the wafer has a higher temperature than the lower side thereof, and accordingly a warp is generated in the form that the upper side of the wafer is convex (upward convex).

If a wafer which is a semiconductor substrate warps while a thin film is being grown on the main surface of the wafer, the state of contact between the main surface of the wafer and the susceptor varies depending on the position on the main surface of the wafer. In the case for example where the heater is provided on the lower side of the susceptor and the wafer therefore warps in the form of a downward convex, the center and a portion therearound of the main surface of the wafer are in contact with the susceptor while the distance between the wafer and the susceptor increases toward the edge of the main surface. In this case, therefore, a central portion of the wafer has a higher temperature than the edge of the wafer. Due to the resultant temperature distribution on the main surface of the wafer, the homogeneity of the thin film grown on the wafer could be degraded.

Further, depending on the type of a thin film to be grown on a main surface of a wafer which is a semiconductor substrate, in the case for example where gallium nitride (GaN) is to be vapor-phase grown on a main surface of a silicon (Si) substrate, an increased warpage (warpage of downward convex) after the film is deposited could cause a crack to be opened in the wafer. As seen from above, the heat transfer and the temperature difference between the upper side and the lower side with respect to the direction along the main surface of the wafer could result in problems such as warpage of the wafer, degradation of the homogeneity, and generation of a crack depending on the case.

The present invention has been made to solve the above-described problems, and an object of the invention is to provide a film deposition apparatus controlling curve of a main surface of a semiconductor substrate due to heating when a thin film is being deposited on the main surface of the semiconductor substrate.

### Means for Solving the Problems

A film deposition apparatus of the present invention includes a susceptor holding a substrate, a first heating member placed to face one main surface of the susceptor, a second heating member placed to face another main surface of the susceptor that is located opposite to the one main surface, and a control unit capable of controlling respective heating temperatures independently of each other of the first heating member and the second heating member.

As described above, the film deposition apparatus including the first heating member placed to face one main surface of the susceptor and the second heating member placed to face another main surface of the susceptor that is located opposite to the one main surface can be used to heat a semiconductor substrate set on the one main surface of the susceptor both from above and from below by the heating members. Accordingly, as compared with the case where a heating member is provided either only above or only below the semiconductor substrate, the temperature difference between the upper side and the lower side is reduced. Therefore, as compared with the case where a heating member is provided either only above or only below the semiconductor substrate to apply heat, the amount of a warpage can be reduced when a thin film is grown on the semiconductor substrate. Further, the temperature difference between the upper side and the lower side of the semiconductor substrate is reduced and accordingly the amount of a warpage of the semiconductor substrate is reduced. Thus, the temperature uniformity of the semiconductor substrate can be improved and a deposited thin film can be made substantially homogeneous across the whole on the main surface of the semiconductor substrate.

Further, a film deposition apparatus of the present invention includes a susceptor holding a substrate, a first heating member placed to face one main surface of the susceptor, a second heating member placed to face another main surface of the susceptor that is located opposite to the one main surface, and a control unit capable of controlling respective heating temperatures independently of each other of the first heating member and the second heating member. Either only one of or both of the first heating member and the second heating member can be operated to apply heat. In other words, the film deposition apparatus of the present invention is also capable of adequately depositing a film by operating only one of the first and second heating members to apply heat. The flow of heat in the film deposition apparatus can therefore be controlled in a desired manner.

Further, the warpage of the semiconductor substrate can be decreased to reduce the possibility of generation of a crack in the semiconductor substrate. Furthermore, the heating members are placed to respectively face one and the other main surfaces with respect to the direction along the main surface of the semiconductor substrate, and thus a concentration gradient due to a temperature difference of a material gas in the ambient facing a main surface of the semiconductor substrate is reduced and occurrence of convection of the material gas can be suppressed. In this way, the quality of a deposited thin film can be improved.

The film deposition apparatus of the present invention may further include a measurement unit measuring a curvature or warpage of the substrate, and may further have a capability that, based on a result of measurement of the curvature or warpage of the substrate, respective heating temperatures of the first heating member and the second heating member are controlled independently of each other with the control unit. With such a capability, while the amount or direction of the curvature of the semiconductor substrate is measured in real time, the result of measurement may be fed back from the control unit to the first and second heating members, so that respective temperatures of the first and second heating members can be controlled in real time to reduce the curvature of the semiconductor substrate. Since the reduced curvature can reduce the warpage, the warpage of the semiconductor substrate can further be reduced. Further, instead of measurement of the curvature of the semiconductor substrate while a film is being deposited, measurement of the warpage of the semiconductor substrate can be taken while a film is being deposited, by means of, for example, a laser beam. Thus, control can be performed using the warpage instead of the above-described curvature.

According to the present invention, the above-described susceptor and the heating members are used to heat the semiconductor substrate. Onto one main surface of the substrate, a material gas of a constituent component of a thin film to be formed is supplied while the semiconductor substrate is heated. Such a method (vapor phase growth) can be used to form a high-quality thin film with crystal arrangement aligned with a crystal plane of the semiconductor substrate. As a material gas for using the above-described method (vapor phase growth), a chloride gas or a hydride gas of a nonmetal material for example may be used. Alternatively, a vapor of an organometallic compound may be used.

A vacuum vapor deposition method may also be used by which a vapor of a constituent component of a thin film of a group III nitride semiconductor for example to be formed on one main surface of the semiconductor substrate is deposited in vacuum while the susceptor and the heating members as described above are used to heat the semiconductor substrate. This method can be used to reduce the film deposition rate or make an in-situ observation of the thin film being deposited.

### EFFECTS OF THE INVENTION

The film deposition apparatus of the present invention can reduce the possibility of occurrence of a warpage and a crack to a substrate and improve the quality of a thin film having been grown.

### BRIEF DESCRIPTION OF THE DRAWINGS

FIG. 1 is a schematic cross section generally showing the inside of a film deposition apparatus depositing a film by the vapor phase growth in a first embodiment of the present invention.

FIG. 2 is a schematic cross section generally showing the inside of a film deposition apparatus 201 including a control unit for controlling the temperature of heaters.

FIG. 3 is a schematic cross section generally showing the inside of a film deposition apparatus depositing a film by the vacuum vapor deposition in a second embodiment of the present invention.

FIG. 4 is a schematic diagram showing a laminate structure of an HEMT epitaxial structure for examining the homogeneity of a thin film having been deposited.

FIG. 5 is a schematic diagram showing a laminate structure of an HEMT epitaxial structure for examining occurrence of a warpage and a crack to a thin film having been deposited.

FIG. 6 is a schematic diagram generally showing the inside of a conventionally-used film deposition apparatus depositing a film by the vapor phase growth.

### MODES FOR CARRYING OUT THE INVENTION

Embodiments of the present invention will hereinafter be described with reference to the drawings. In the embodiments, components carrying out the same functions are denoted by the same reference characters, and a description thereof will not be repeated unless otherwise required.

### First Embodiment

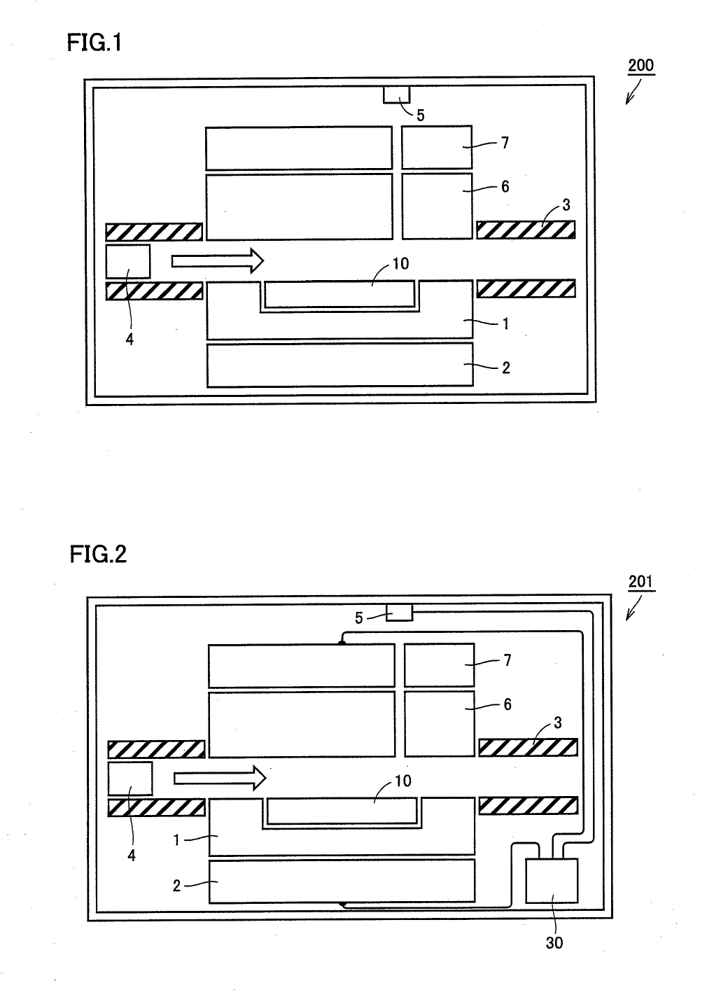

As shown in FIG. 1, a film deposition apparatus 200 for depositing a film by the vapor phase growth in a first embodiment of the present invention includes, above a susceptor 1 for setting a wafer which is a substrate, for example, a semiconductor substrate 10, a heater 7 placed to face an upper main surface of susceptor 1 and serving as a first heating member. Further, as shown in FIG. 1, in a region between susceptor 1 and heater 7 located above susceptor 1, a heating jig 6 is placed. It should be noted that a main surface herein refers to a surface of semiconductor substrate 10 or susceptor 1 for example that has the largest area and is set along the horizontal direction. In addition, growth and deposition of a film used herein are substantially synonymous with each other.

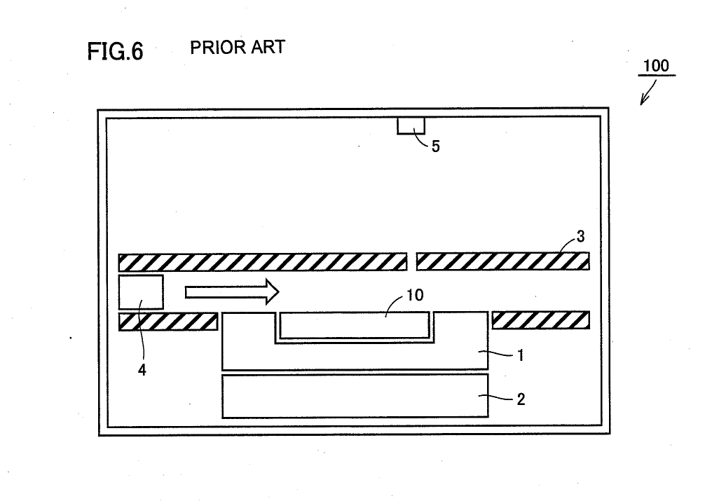

The structure of film deposition apparatus 200 is the same as that of film deposition apparatus 100 described above and shown in FIG. 6, except for the above-described features. Namely, below susceptor 1 as well, a heater 2 placed to face a lower main surface of susceptor 1 and serving as a second heating member is included. Above susceptor 1, a flow channel 3 for flowing a material gas therein is placed. While heater 7 and heater 2 heat susceptor 1 and semiconductor substrate 10 thereon, a material gas of a constituent component of a thin film to be deposited is supplied into flow channel 3 from a material gas nozzle 4 placed at one end (upstream) of flow channel 3, so that one main surface (upper main surface shown in FIG. 1) of semiconductor substrate 10 is exposed to this material gas. Accordingly, on the main surface of heated semiconductor substrate 10, a thin film constituted of the supplied material gas is deposited. At this time, a laser beam applied from a module 5 placed on the ceiling (upper side) in film deposition apparatus 200 can be used to measure the curvature or warpage of semiconductor substrate 10 as described later, namely the extent of a curve with respect to the direction along the main surface of semiconductor substrate 10. It should be noted here that, while the curvature and the warpage are both quantitative indices of the extent to which semiconductor substrate 10 curves, the curvature is an index representing the extent of the curve at a certain point on the main surface of semiconductor substrate 10, and the warpage is an index representing the extent of the curve of the whole main surface of semiconductor substrate 10 or the shape of the main surface of semiconductor substrate 10 resulting from the curve.

It should be noted that FIG. 1 shows that heating jig 6, heater 7 and flow channel 3 are each partially discontinuous in the lateral direction, so that it can easily be seen that the laser beam emitted from module 5 is transmitted onto the main surface of semiconductor substrate 10. Therefore, as long as the laser beam from module 5 can be passed through, heating jig 6 and heater 7 as used may be members continuous in the lateral direction. While FIG. 1 shows that the laser beam from module 5 is applied from above, module. 5 may be set near a side of flow channel 3 for example to apply a laser beam, which can pass through flow channel 3, obliquely relative to the direction of the main surface of semiconductor substrate 10, onto the main surface of semiconductor substrate 10. In this case, heating jig 6 and heater 7 should be continuous in the lateral direction. In any case, FIG. 1 is a cross section and actually heating jig 6, heater 7, and flow channel 3 are each a one-piece component.

As described above, susceptor 1 is provided for setting semiconductor substrate 10. In addition, susceptor 1 and heating jig 6 each have the function of uniformly transferring the heat of the heater to semiconductor substrate 10. Specifically, heating jig 6 and susceptor 1 allow the heat generated by heater 7 and the heat generated by heater 2 respectively to be transmitted uniformly to semiconductor substrate 10. Susceptor 1 and heating jig 6 are both made of carbon (C) coated with silicon carbide (SiC) for example. Silicon carbide has high heat conductivity and excellent heat resistance and can therefore smoothly transmit the heat to semiconductor substrate 10. As a material for susceptor 1 and heating jig 6, quartz, sapphire, SiC, carbon coated with pyrolytic carbon, boron nitride (BN), and tantalum carbide (TaC) for example may be used in addition to the above-described material.

Flow channel 3 is a pipe provided for supplying a material gas onto a main surface of semiconductor substrate 10. As a material for flow channel 3, quartz for example is used. In addition to this, for example, carbon coated with a thin SiC film, sapphire, SiC, carbon coated with pyrolytic carbon, BN, TaC, SUS, and nickel (Ni) may be used. From material gas nozzle 4, a gas of a constituent material for a thin film to be formed is supplied into flow channel 3. At this time, as semiconductor substrate 10 is heated by heater 7 and heater 2, the material gas fed onto the main surface of semiconductor substrate 10 is thermally decomposed so that a crystal (thin film) can be formed on the main surface of semiconductor substrate 10.

For example, it is supposed that a sapphire substrate (c plane) is used as semiconductor substrate 10 to form a thin film of a group III compound semiconductor on one main surface of the sapphire substrate. In this case, as a gas fed onto the main surface of semiconductor substrate 10 from material gas nozzle 4, a vapor of a liquid or solid organometallic compound formed by adding a methyl group (—CH₃) to a constituent metal of a thin film and having a high vapor pressure at room temperature, and a hydride gas of a nonmetal material are used. A metal organic vapor phase growth method (MOVPE) by which these gases are sprayed onto the main surface of heated semiconductor substrate 10 and thermally decomposed to obtain a semiconductor crystal can be used to deposit a thin film of a group III compound semiconductor on the main surface of semiconductor substrate 10. As seen from above, the heater(s) applies heat to thermally decompose the supplied gas and deposit the resultant crystal in the form of a thin film.

Alternatively, a vapor phase growth method (VPE) using a chloride gas as a gas to be supplied onto the main surface of semiconductor substrate 10 from material gas nozzle 4 may also be used. In particular, a vapor phase growth method using a chloride gas and a hydride gas of a nonmetal material is referred to as hydride vapor phase growth method (H-VPE). These material gases are sprayed onto a main surface of heated semiconductor substrate 10 and thermally decomposed so that a semiconductor crystal is obtained. Film deposition apparatus 200 can be used to perform any of the above-described MOVPE, VPE, and H-VPE.

Here, it is supposed for example that conventional film deposition apparatus 100 shown in FIG. 6 in which only heater 2 is located below susceptor 1 is used to deposit a film at 1050° C. Then, the heat generated by heater 2 is transmitted from the lower side to the upper side of susceptor 1, and from the lower side to the upper side of semiconductor substrate 10 (sapphire substrate) set on the upper side of susceptor 1. Further, because of radiation to above semiconductor substrate 10 and transfer of heat to the material gas, a large amount of heat flows. The large amount of heat transferred from the lower side toward the upper side is also transmitted from the lower side to the upper side of the main surface of the sapphire substrate. At this time, a temperature gradient is generated between the lower side and the upper side of the main surface of the sapphire substrate. The temperature gradient (temperature difference) between the lower side and the upper side of the main surface of the sapphire substrate causes a large curvature of the main surface of the sapphire substrate, resulting in a warpage with respect to the direction along the main surface of the sapphire substrate.

Further, the radiant heat and the like from the lower side toward the upper side of susceptor 1 also causes a gradient of the temperature of the material gas supplied into flow channel 3 and accordingly promotes convection of the gas. Then, the material gas supplied from material gas nozzle 4 and passing on the main surface of semiconductor substrate 10 moves up and down repeatedly due to convection of the gas. Such gas convection hinders stable vapor phase growth on the main surface of semiconductor substrate 10.

It is seen from above that the temperature gradient (temperature difference) between the lower side and the upper side of the main surface of semiconductor substrate 10 (sapphire substrate) can be reduced and the convection of the material gas can be reduced to adequately perform the vapor phase growth on the main surface of semiconductor substrate 10 while suppressing a warpage of semiconductor substrate 10. In order to achieve this, the present invention adds, to conventional film deposition apparatus 100 shown in FIG. 6, heater 7 placed to face the upper main surface of susceptor 1 and serving as a first heating member, and places heating jig 6 in the region between susceptor 1 and heater 7 located above susceptor 1 to configure film deposition apparatus 200 shown in FIG. 1 and use this apparatus to heat semiconductor substrate 10.

Thus, semiconductor substrate 10 set on one main surface of susceptor 1 is heated both from above and from below by the heating members. Then, as compared with the case for example where a heating member is provided either only above or only below semiconductor substrate 10 to apply heat like film deposition apparatus 100 shown in FIG. 6, the temperature difference between the upper side and the lower side is smaller. Therefore, as compared with the case where the heating member is provided either only above or only below semiconductor substrate 10, the curvature which is an extent of a curve of the main surface of semiconductor substrate 10 when a thin film is grown on semiconductor substrate 10 can be reduced and the amount of a warpage can be decreased.

It should be noted that only one of heater 7 and heater 2 for example may be operated to apply heat as required in film deposition apparatus 200. For example, when only heater 2 is operated to apply heat while heater 7 is not operated in film deposition apparatus 200, film deposition apparatus 200 can function similarly to film deposition apparatus 100 shown in FIG. 6. In other words, film deposition apparatus 200 has a capability to adequately deposit a film using only one of heater 7 and heater 2. Further, respective heating temperatures of heater 7 and heater 2 can be set independently of each other to desired heating temperatures respectively. The flow of heat in film deposition apparatus 200 can thus be controlled in a manner as desired.

It should be noted that, in the case above, an increased temperature difference between the upper side and the lower side with respect to the main surface of semiconductor substrate 10 could result in an increased amount of a warpage of semiconductor substrate 10, as described above. However, only one of heater 7 and heater 2 can be operated for the purpose of correcting a warpage of semiconductor substrate 10 where the substrate has the warpage of a considerable extent initially (before a film is deposited), simultaneously with depositing the film. Thus, heater 7 and heater 2 can be set to respective desired heating temperatures independently of each other, which includes the case where only one of heater 7 and heater 2 is operated to apply heat.

Two heating members are placed to respectively face one (upper) and the other (lower) main surfaces of semiconductor substrate 10 with respect to the direction of the main surfaces. Thus, a concentration gradient due to a temperature difference of the material gas in the ambient facing the main surface of semiconductor substrate 10 is reduced and generation of convection of the material gas can be suppressed. The material gas therefore flows stably from upstream toward downstream in the pipe of flow channel 3. In this way, the vapor phase growth can be carried out stably on the main surface of semiconductor substrate 10 and the quality of the grown thin film can be improved.

The curvature which is an extent to which a main surface of semiconductor substrate 10 curves is reduced to decrease the amount of the warpage. Thus, the state of contact between the main surface of semiconductor substrate 10 and susceptor 1 can be made substantially constant regardless of the position on the main surface of semiconductor substrate 10, namely at a central portion and at the edge of semiconductor substrate 10. Therefore, the temperature of the main surface of semiconductor substrate 10 can be made substantially constant regardless of the position on the main surface. In this way, the temperature distribution on the main surface of semiconductor substrate 10 is kept substantially constant and thus a thin film deposited on semiconductor substrate 10 can be made substantially homogeneous.

Further, the warpage when a film is deposited on semiconductor substrate 10 is controlled in such manner that reduces the warpage of semiconductor substrate 10 after the film is deposited and after the temperature is decreased. Thus, the possibility of generation of a crack in semiconductor substrate 10 can be reduced. For example, in general, where a substrate (semiconductor substrate 10) and a film to be grown on the substrate have respective coefficients of thermal expansion different from each other and the temperature is decreased after the film is deposited, the substrate could have a large warpage resulting in generation of a crack in the substrate. However, while the film is being deposited, a warpage in the direction opposite to the direction of the warpage generated due to the properties of this substrate for example may be generated to reduce (correct) the warpage generated due to the properties of the substrate while the film is being deposited. In this way, occurrence of the warpage and the crack to the substrate after the film is deposited thereon can be suppressed. This can be achieved by the fact that film deposition apparatus 200 can also operate only one of heater 7 and heater 2 to apply heat and can independently and freely control respective temperatures of heater 7 and heater 2.

As to the material for semiconductor substrate 10 on which a thin film is deposited, a sapphire substrate, a Si wafer, or a wafer (substrate) of a compound semiconductor such as GaN, SiC, aluminum nitride (AlN), or aluminum gallium nitride (AlGaN), for example, may be used.

The curvature which is an extent of a curve with respect to the direction along the main surface of semiconductor substrate 10 and at a certain point on the main surface, and is used to know the amount of a warpage occurring to semiconductor substrate 10 due to heating by heater 2 and heater 7, can be measured with a laser beam applied from module 5 which is a measuring unit placed on the ceiling (upper side) in film deposition apparatus 200, for example. As described above, module 5 may be set near a side of flow channel 3 for example and a laser beam that can pass through flow channel 3 may be applied from module 5 onto the main surface of semiconductor substrate 10 obliquely with respect to the main surface of semiconductor substrate 10.

The warpage of semiconductor substrate 10 while a film is being deposited is determined by a calculation made by module 5 from the curvature measured by module 5 (in-situ monitor). As module 5 for measuring the warpage of semiconductor substrate 10 while a film is being deposited, a commercially available one may be used. Alternatively, module 5 of a type measuring the curvature at a certain point on the main surface of semiconductor substrate 10 and then calculating the warpage may be used, or module 5 of a type capable of measuring the warpage (shape) of the whole semiconductor substrate 10 may be used. In order to measure the warpage of the whole semiconductor substrate 10 after the film is deposited, above-described module 5 may be used, or a step height scale or profilometer for example may also be used.

A film deposition apparatus 201 shown in FIG. 2 is configured to further include a control unit 30 for controlling the temperatures of heater 7 and heater 2 in addition to the components of film deposition apparatus 200 shown in FIG. 1. Control unit 30 is connected to module 5 and, in accordance with the result of measurement, taken by module 5, of the curvature with respect to the direction along the main surface of semiconductor substrate 10, control unit 30 can control respective heating temperatures of heater 7 and heater 2 independently of each other in real time so that the curvature of semiconductor substrate 10 has a predetermined value. Control unit 30 connected to module 5 is connected to heater 7 and heater 2 to control respective heating temperatures of heater 7 and heater 2 independently of each other in real time, and thereby control the curvature (warpage) of semiconductor substrate 10 and accordingly enable the heating temperatures to be set to those that can reduce the amount of the warpage of semiconductor substrate 10. Such control can be repeated to deposit a thin film on one main surface of semiconductor substrate 10 while controlling the curvature and the amount of the warpage with respect to the direction along the main surface of semiconductor substrate 10.

### Second Embodiment

As shown in FIG. 2, a film deposition apparatus 301 depositing a film by the vapor phase growth in a second embodiment of the present invention is configured to include material vessels called Knudsen cell 71 and Knudsen cell 72 and each having a pinhole at an end of a cylindrical shape for feeding a vapor of a constituent component of a thin film to be deposited onto one main surface of a substrate which is for example semiconductor substrate 10. Film deposition apparatus 301 has a capability (not shown) of generating a vacuum in the apparatus.

Knudsen cell 71 and Knudsen cell 72 are used to heat and evaporate a material in a vacuum higher than that of the outer space and feed from the pinhole a jet stream (molecular beam), in which the direction of travel of evaporated molecules is aligned, onto a main surface of heated semiconductor substrate 10, so as to allow crystal growth to be achieved for a thin film of a group III nitride semiconductor for example to be deposited on the main surface of semiconductor substrate 10. The film deposition method as described above by which a molecular beam in which the direction of travel of a vapor of a constituent component for a thin film to be deposited is aligned is applied in a vacuum to deposit the film on one main surface of a substrate is called molecular beam epitaxy (MBE).

When a thin film of AlN is to be deposited on one main surface of semiconductor substrate 10, for example, Knudsen cell 71 and Knudsen cell 72 are first filled with aluminum (Al) and nitrogen (N) respectively. Then, Knudsen cell 71 is heated to evaporate Al. While N contained in Knudsen cell 72 is a gaseous state at room temperature and requires no heating, Knudsen cell 72 when filled with a metal material for example is heated similarly to Knudsen cell 71 to evaporate the material. From the pinhole at the end of the Knudsen cell, a jet stream (molecular beam) is applied in vacuum onto one main surface of heated semiconductor substrate 10. Then, Al molecules and N molecules arriving on the main surface of semiconductor substrate 10 are attached and bonded to each other on the main surface of heated semiconductor substrate 10 to form an MN crystal. Namely, this is a vacuum-vapor-deposited AlN thin film. Because the MBE method is a non-equilibrium system and is a method using no chemical reaction process, the MBE method is a film deposition method appropriate for analysis of a crystal growth mechanism and growth of an ultrathin film.

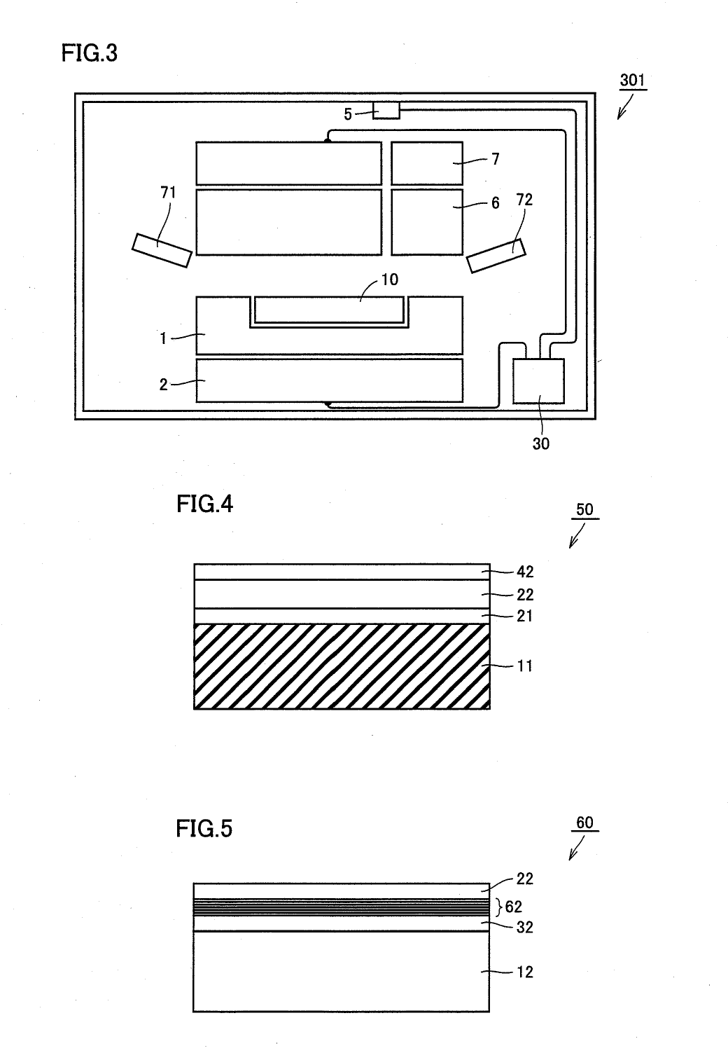

While two Knudsen cells are placed in film deposition apparatus 301 in FIG. 3, the number of Knudsen cells may be increased depending on the type of a thin film to be deposited. For example, when a thin film of three-component gallium aluminum arsenide (GaAlAs) is to be deposited, three Knudsen cells may be placed.

The second embodiment of the present invention differs from the first embodiment of the present invention only in that film deposition apparatus 301 using the MBE method based on the vacuum vapor deposition as described above is employed. Specifically, as shown in FIG. 3, in film deposition apparatus 301 as well, semiconductor substrate 10 is set on susceptor 1, and heater 7 placed to face the upper main surface of susceptor 1 and serving as a first heating member and heater 2 placed to face the lower main surface of susceptor 1 and serving as a second heating member are included. The two heaters transmit heat to semiconductor substrate 10 via susceptor 1 and heating jig 6 respectively. The structure in which semiconductor substrate 10 set on one main surface of susceptor 1 is thus heated both from above and from below by the heating members is identical for example to film deposition apparatus 200 shown in FIG. 1 and film deposition apparatus 201 shown in FIG. 2.

In terms of the above-described features only, the present embodiment differs from the first embodiment of the present invention. In other words, the structure, conditions, procedures, effects, and the like that are not described above in connection with the second embodiment of the present invention all conform to the first embodiment of the present invention.

### Example 1

Example 1 is an example in which the film deposition apparatus of the present invention was used to improve the homogeneity of a deposited thin film and the curvature of a laminate structure. Samples of a sapphire laminate structure 50 as an epitaxial laminate structure shown in FIG. 4 were formed by the methods illustrated below. In the laminate structure, on one main surface (upper one in FIG. 4) of a 6-inch sapphire substrate 11 (c plane) provided as semiconductor substrate 10 (see FIGS. 1 to 3), respective thin films of 25 nm-thick low-temperature GaN 21, a 2 μm-thick GaN 22, and a 25 nm-thick AlGaN 42 containing 25 mass % of Al are superposed in this order.

As to Sample 1, conventionally-used film deposition apparatus 100 shown in FIG. 6 was used to form sapphire laminate structure 50 shown in FIG. 4. Here, a thermocouple which is not shown in FIG. 6 was used to measure temperature T of the main surface of sapphire substrate 11 in sapphire laminate structure 50. When low-temperature GaN 21 was deposited, T was 500° C. When GaN 22 and AlGaN 42 were each deposited, T was 1050° C. Under this condition, the metal organic vapor phase growth method (MOVPE method) was used to deposit GaN 22 and AlGaN 42.

As to Sample 2, film deposition apparatus 200 in the first embodiment of the present invention shown in FIG. 1 was used to form sapphire laminate structure 50 shown in FIG. 4 under the condition that only heater 2 was operated to apply heat while heater 7 was not operated to apply heat. The heating temperature of heater 2 conformed to the heating temperature at which Sample 1 was prepared. Specifically, a thermocouple which is not shown in FIG. 1 was used to measure temperature T of the main surface of sapphire substrate 11 in sapphire laminate structure 50. When low-temperature GaN 21 was deposited, T was 500° C. When GaN 22 and AlGaN 42 were each deposited, T was 1050° C. Under this condition, the metal organic vapor phase growth method (MOVPE method) was used to deposit GaN 22 and AlGaN 42. Other conditions for depositing the film conformed to those under which the film for Sample 1 was deposited.

As to Sample 3, film deposition apparatus 200 in the first embodiment of the present invention shown in FIG. 1 was used to form sapphire laminate structure 50 shown in FIG. 4 while both of heater 2 and heater 7 were operated to apply heat. At this time, temperature T of the main surface of sapphire laminate structure 50 conformed to the temperature at which Samples 1 and 2 were prepared. Specifically, a thermocouple which is not shown in FIG. 1 was used to measure temperature T of the main surface of sapphire substrate 11 in sapphire laminate structure 50. When low-temperature GaN 21 was deposited, T was 500° C. When GaN 22 and AlGaN 42 were each deposited, T was 1050° C. Under this condition, the metal organic vapor phase growth method (MOVPE method) was used to deposit GaN 22 and AlGaN 42. Respective outputs (heating temperatures) of heater 7 and heater 2 were adjusted so that T was set to the above-described temperatures, and the film was deposited while adjustments were made to make substantially identical respective outputs of heater 7 and heater 2. Other conditions for depositing the film conformed to those under which the film for Sample 1 was deposited.

As to Sample 4, film deposition apparatus 200 in the first embodiment of the present invention shown in FIG. 1 was used to form sapphire laminate structure 50 shown in FIG. 4 while both of heaters 2 and heater 7 were operated to apply heat. At this time, temperature T of the main surface of sapphire substrate 11 in sapphire laminate structure 50 conformed to the temperature at which above-described Samples 1 to 3 were prepared. Here again, the metal organic vapor phase growth method (MOVPE method) was used to deposit the films. Respective outputs (heating temperatures) of heaters 7 and 2 were adjusted so that T was set to the above-described temperatures, and the curvature (or warpage) of sapphire laminate structure 50 was substantially zero during deposition of the films, specifically the ratio between respective outputs of heater 7 and heater 2 was approximately 67:33. Other conditions for depositing the film conformed to those under which the film for Sample 1 was deposited.

For Samples 1 to 4 prepared through the above-described procedures, the curvature with respect to the direction along the main surface of sapphire laminate structure 50 (curvature of the substrate), the direction of a warpage of sapphire laminate structure 50 (warpage of the substrate), the sheet resistance (distribution of the sheet resistance), and the sheet resistance at a central portion of the main surface of sapphire substrate 11 (sheet resistance of the central portion) were measured. The curvature of the substrate was measured with an in-situ monitor provided as module 5 (see FIG. 2) while AlGaN film 42 was being deposited. As to the sheet resistance, a non-contact sheet resistance measurement device was used after the film was deposited to evaluate two-dimensional electron gas characteristics. The results of measurement are shown in Table 1 below. In Table 1, respective structures and measurement data of Samples 1 to 4 in Example 1 are summarized.

TABLE 1

| | Sample 1 | Sample 2 | Sample 3 | Sample 4 |
|---|---|---|---|---|
| film deposition | conventional | present | present | present |
| apparatus | | invention | invention | invention |
| heating by | (lower) heater 2 | (lower) heater 2 | (upper) heater 7 & | (upper) heater 7 & |
| heater(s) | only | only | (lower) heater 2 | (lower) heater 2 |
| output ratio | — | — | outputs of (upper) | output ratio between |
| between heaters | | | heater 7 and (lower) | (upper) heater 7 and |
| | | | heater 2 are | (lower) heater 2 is |
| | | | substantially | 67:33 |
| | | | identical | |
| curvature of | 120 km⁻¹ | 110 km⁻¹ | 25 km⁻¹ | 0 km⁻¹ |
| substrate | | | | |
| warpage of | concave | concave | concave | none |
| substrate | | | | |
| sheet resistance | 491 ± 62 Ω/sq | 485 ± 52 Ω/sq | 431 ± 11 Ω/sq | 426 ± 4 Ω/sq |
| distribution | | | | |
| sheet resistance of | 433 Ω/sq | 431 Ω/sq | 426 Ω/sq | 423 Ω/sq |
| central portion | | | | |

As seen from Table 1, the same results were obtained from the case (Sample 1) where conventionally-used film deposition apparatus 100 in which heater 2 was placed only below susceptor 1 was used, and the case (Sample 2) where film deposition apparatus 200 of the present invention was used while only heater 2 below susceptor 1 was operated to apply heat. Specifically, while the film of AlGaN 42 was being deposited, the main surface of sapphire laminate structure 50 curved with a large curvature in a concave form, namely downward convex form. As to the sheet resistance, the distribution of Sample 1 was ±62 Ω/sq and that of Sample 2 was ±52 Ω/sq, from which it was found that the homogeneity of the grown thin film was not maintained. Regarding Sample 1, the value of the sheet resistance of a central portion of the main surface was a relatively favorable result of approximately 433 Ω/sq. The sheet resistance, however, increased from the central portion toward the edge, and the distribution was deteriorated. Regarding Sample 2 as well, the value of the sheet resistance of a central portion of the main surface was a relatively favorable result of approximately 431 Ω/sq. The sheet resistance, however, increased from the central portion toward the edge, and the distribution was deteriorated. It was accordingly found that, when only the lower side of susceptor 1 was heated, the temperature gradient (temperature difference) between the lower side and the upper side of sapphire laminate structure 50 increased, which caused a large curve, a large temperature distribution within the main surface of sapphire laminate structure 50, and deteriorated distribution of the sheet resistance.

In contrast, like Sample 3 for example, when both of the heaters above and below susceptor 1 were operated to apply heat, the curvature of sapphire laminate structure 50 while the film of AlGaN 42 was being deposited was smaller. The sheet resistance distribution was also improved to ±11 Ω/sq, and the homogeneity of the grown thin film was improved. The value of the sheet resistance at a central portion was also a favorable value of 426Ω.

It should be noted that, when respective outputs of heater 7 and heater 2 above and below susceptor 1 were made substantially identical, a concave curve was still generated while the curvature was small. Further, the value of the sheet resistance considerably increased from the central portion toward the edge of the main surface. From the results of Samples 1 to 3, it is seen that the central portion of sapphire laminate structure 50 curves toward a higher-temperature side when there is a temperature gradient (temperature difference) between the lower side and the upper side of the main surface. Then, in order to achieve a curvature of zero, the output of upper heater 7 on the lower-temperature side was increased, and accordingly respective values of the curvature and the warpage were substantially zero and a remarkably improved sheet resistance distribution of ±4 Ω/sq was achieved like Sample 4. The sheet resistance of the central portion also had a favorable value of 423Ω. In this case, a considerably increased value of the sheet resistance was not confirmed even at a position closer to the edge relative to the central portion of the main surface.

As heretofore described, the MOVPE apparatus enabling independent control by means of control unit 30 capable of controlling respective heating temperatures of heater 7 as a first heating member and heater 2 as a second heating member independently of each other was used, and thus the homogeneity of the thin film formed on the main surface of sapphire laminate structure 50 could be remarkably improved.

Both of the heaters below and above susceptor 1 can be operated to apply heat and thereby reduce a temperature gradient (temperature difference) between the lower side and the upper side of flow channel 3 (see FIG. 2) to suppress occurrence of convection of the material gas in the ambient facing the main surface of sapphire laminate structure 50. The material gas accordingly flows stably from upstream to downstream in the pipe of flow channel 3. It is therefore seen that film deposition can be performed stably on the main surface of sapphire laminate structure 50, and characteristics such as the sheet resistance distribution of sapphire laminate structure 50 have been improved.

In addition, the suppression of thermal convection suppresses additional reaction and polymerization reaction due to the convection. It is also seen that the suppression of the additional reaction and polymerization reaction provides the effect that the characteristics are also improved.

The curvature which is an extent of a curve can be reduced by operating both of the heaters below and above the main surface of susceptor 1 to apply heat and thereby reducing the temperature gradient (temperature difference) between the lower side and the upper side of the main surface of sapphire laminate structure 50. The reduced curvature enables the state of contact between the main surface of sapphire laminate structure 50 and susceptor 1 to be substantially constant regardless of the position on the main surface of sapphire laminate structure 50, namely at the central portion and the edge of sapphire laminate structure 50. The temperature of the main surface can therefore be made substantially constant regardless of the position on the main surface. It is seen that the grown thin film has been enabled to be substantially homogeneous by keeping substantially constant the temperature distribution on the main surface as described above.

It is noted that the warpage occurring to sapphire laminate structure 50 while the thin film is being deposited varies depending on thin-film growth conditions such as the heating temperature and the type and amount of the material gas to be supplied, as well as the type of sapphire laminate structure 50 and the type of the substrate to be used, for example. Thus, the temperature gradient (temperature difference) between the lower side and the upper side of the main surface of susceptor 1 also varies depending on the above-described thin-film growth conditions. It is therefore preferable that, each time the thin-film growth conditions are changed, the ratio between respective outputs of heaters 7 and 2 is also changed independently of each other.

### Example 2

Example 2 is an example in which the film deposition apparatus of the present invention was used to improve the amount of a warpage of a laminate structure with deposited films and suppress a crack. Samples of a silicon laminate structure 60 as an epitaxial laminate structure shown in FIG. 5 were formed by the methods illustrated below. In the laminate structure, on one main surface (upper one in FIG. 5) of a 5-inch silicon substrate 12 (orientation was the direction along a (111) plane and the thickness was 700 μm) provided as semiconductor substrate 10 (see FIGS. 1 to 3), a 100 nm-thick film of AlN 32, and 40 layers of a pair laminate 62 constituted of a 25 nm-thick GaN film and a 5 nm-thick AN film to have the total thickness of 1.2 μm were superposed in this order. On pair laminate 62, a 1.2 μm-thick thin film of GaN 22 was further superposed.

In the case where a nitride semiconductor epitaxial layer is grown on the main surface of silicon substrate 12 and when the temperature is decreased after the layer is deposited, a difference between respective coefficients of thermal expansion of silicon substrate 12 and the grown nitride semiconductor epitaxial layer causes a large warpage in a downward convex form and could further cause a crack in the nitride semiconductor epitaxial layer. In view of this, Example 2 examined the warpage and whether or not a crack was generated when the films were deposited on silicon substrate 12.

As to Sample 5, conventionally-used film deposition apparatus 100 shown in FIG. 6 was used to form silicon laminate structure 60 shown in FIG. 5. Here, a thermocouple which is not shown in FIG. 6 was used to measure temperature T of the main surface of silicon substrate 12 in silicon laminate structure 60. Under the condition that T was 1050° C. when each of the above-described thin films was deposited, the metal organic vapor phase growth method (MOVPE method) was used to deposit AlN 32, pair laminate 62, and GaN 22.

As to Sample 6, film deposition apparatus 200 in the first embodiment of the present invention shown in FIG. 1 was used to form silicon laminate structure 60 shown in FIG. 5 under the condition that only heater 2 was operated to apply heat while heater 7 was not operated to apply heat. The heating temperature of heater 2 conformed to the heating temperature at which Sample 5 was prepared. Specifically, a thermocouple which is not shown in FIG. 1 was used to measure temperature T of the main surface of silicon substrate 12 in silicon laminate structure 60. Under the condition that T when the above-described films were each deposited was 1050° C., the metal organic vapor phase growth method (MOVPE method) was used to deposit respective films of AlN 32, pair laminate 62, and GaN 22. Other conditions for depositing the film conformed to those under which the film for Sample 5 was deposited.

As to Sample 7, film deposition apparatus 200 in the first embodiment of the present invention shown in FIG. 1 was used to form silicon laminate structure 60 shown in FIG. 5 under the condition that only heater 7 was operated to apply heat while heater 2 was not operated to apply heat. The heating temperature of heater 7 conformed to the heating temperature at which Sample 5 was prepared. Specifically, a thermocouple which is not shown in FIG. 1 was used to measure temperature T of the main surface of silicon substrate 12 in silicon laminate structure 60. Under the condition that T when the above-described films were each deposited was 1050° C., the metal organic vapor phase growth method (MOVPE method) was used to deposit respective films of AlN 32, pair laminate 62, and GaN 22. Other conditions for depositing the film conformed to those under which the film for Sample 5 was deposited.

For Samples 5 to 7 prepared through the above-described procedures, the direction of a warpage at an increased temperature and with respect to the direction along the main surface of silicon laminate structure 60 (warpage of the substrate at an increased temperature of 1050° C.), the curvature at an increased temperature (curvature of the substrate at an increased temperature of 1050° C.), the magnitude of the warpage after film deposition (amount of the warpage of the substrate after film deposition), and whether or not a crack was occurred were measured. The curvature was measured with an in-situ monitor provided as module 5 (see FIG. 2) when the temperature of silicon substrate 12 had been increased to 1050° C. The warpage was measured with the in-situ monitor provided as module 5 when the temperature had been increased to 1050° C. and after the film deposition. Whether or not a crack was generated was evaluated after the film deposition by means of an optical microscope. The results of the measurement and evaluation are shown in Table 2 below. In Table 2, respective structures and measurement data of Samples 5 to 7 in Example 2 are summarized.

TABLE 2

| | Sample 5 | Sample 6 | Sample 7 |
|---|---|---|---|
| film deposition | conventional | present | present |
| apparatus | | invention | invention |
| heating by heater(s) | (lower) heater | (lower) heater | (upper) heater |
| | 2 only | 2 only | 7 only |
| warpage of substrate at | concave | concave | convex |
| an increased | | | |
| temperature of 1050° C. | | | |
| curvature of substrate | 40 km⁻¹ | 40 km⁻¹ | −30 km⁻¹ |
| at an increased | | | |
| temperature of 1050° C. | | | |
| amount of substrate | 100 μm | 90 μm | 30 μm |
| warpage after film | | | |
| deposition | | | |
| crack | cracked | cracked | no crack |

As seen from Table 2, similar results were obtained from the case where conventionally-used film deposition apparatus 100 in which heater 2 was placed only below susceptor 1 was used (Sample 5), and the case where film deposition apparatus 200 of the present invention was used while only heater 2 below susceptor 1 was operated to apply heat (Sample 6). Specifically, when the temperature of silicon substrate 12 had been increased to 1050° C., the main surface of silicon substrate 12 to later form silicon laminate structure 60 curved with a large curvature (both with 40 km⁻¹) in a concave form, namely downward convex. In both of Samples 5 and 6 where film deposition had been completed, a large warpage of approximately 100 μm occurred and a crack was generated.

In the case where film deposition apparatus 200 of the present invention was used while only heater 7 above susceptor 1 was operated to apply heat (Sample 7) and when the temperature of silicon substrate 12 had been increased to 1050° C., the main surface of silicon substrate 12 to later form silicon laminate structure 60 curved in a convex form, namely the central portion warped upward (upward convex), and the curvature was 30 km⁻¹ in absolute value. In Sample 7 where film deposition had been completed, the warpage was 30 μm which was remarkably smaller than Samples 5 and 6, and no crack was generated.

What has been found from the results above is as follows. Usually a nitride semiconductor epitaxial layer on silicon substrate 12 warps in a concave form at a decreased temperature due to a difference in coefficient of thermal expansion between silicon and the nitride semiconductor and a crack is likely to be generated. Although the ordinary film deposition method by which silicon laminate structure 60 is heated only from below causes silicon laminate structure 60 to considerably curve in a concave form, silicon laminate structure 60 can be heated from above to suppress (correct) the curve in the concave form of silicon laminate structure 60 and rather cause the structure to curve in a convex form, and thereby suppress the warpage of grown silicon laminate structure 60 and generation of a crack. Further, from a comparison between respective extents of the curve or warpage of Samples 5, 6 and 7, it is also seen that, because silicon laminate structure 60 is likely to warp in a concave form, suppression of the warpage in the concave form will suppress generation of a crack.

It should be construed that embodiments and examples disclosed herein are by way of illustration in all respects, not by way of limitation. It is intended that the scope of the present invention is defined by claims, not by the description above, and encompasses all modifications and variations equivalent in meaning and scope to the claims.

### INDUSTRIAL APPLICABILITY

The film deposition apparatus of the present invention is particularly excellent as a technique of improving the warpage of a substrate on which films are deposited, and thereby improving the homogeneity of the film quality of the substrate and suppressing a crack of the substrate.

### DESCRIPTION OF THE REFERENCE SIGNS

1 susceptor; 2 heater; 3 flow channel; 4 material gas nozzle; 5 module; 6 heating jig; 7 heater; 10 semiconductor substrate; 11 sapphire substrate; 12 silicon substrate; 21 low-temperature GaN; 22 GaN; 30 control unit; 32 AlN; 42 AlGaN; 50 sapphire laminate structure; 60 silicon laminate structure; 62 pair laminate; 71 Knudsen cell; 72 Knudsen cell; 100 film deposition apparatus; 200 film deposition apparatus; 201 film deposition apparatus; 301 film deposition apparatus.

1. A film deposition apparatus comprising:
a susceptor holding a substrate;
a first heating member placed to face one main surface of said susceptor;
a second heating member placed to face another main surface of said susceptor that is located opposite to said one main surface; and
a control unit capable of controlling respective heating temperatures independently of each other of said first heating member and said second heating member.

2. The film deposition apparatus according to claim 1, wherein
either only one of or both of said first heating member and said second heating member being able to be operated to apply heat.

3. The film deposition apparatus according to claim 1, further comprising a measurement unit measuring a curvature or warpage of said substrate, wherein
based on a result of measurement of the curvature or warpage of said substrate, respective heating temperatures of said first heating member and said second heating member are controlled independently of each other.

4. The film deposition apparatus according to claim 1, wherein
onto said one main surface of said substrate, a material gas of a constituent component of a thin film to be formed is supplied.

5. The film deposition apparatus according to claim 4, wherein
said material gas includes a chloride gas.

6. The film deposition apparatus according to claim 4, wherein
said material gas includes a hydride gas of a nonmetal material.

7. The film deposition apparatus according to claim 4, wherein
said material gas includes a vapor of an organometallic compound.

8. The film deposition apparatus according to claim 4, wherein
said thin film is a group III nitride semiconductor.

9. The film deposition apparatus according to claim 1, wherein
on said one main surface of said substrate, a vapor of a constituent component of a thin film to be formed is deposited in vacuum.
